(19) United States
(12) Patent Application Publication
(10) Pub. No.: US 2007/0241366 A1
(43) Pub. Date: Oct. 18, 2007

(54) Field effect transistor with shifted gate

(75) Inventors: Samson Mil'shtein, Chelmsford, MA (US); Christopher Liessner, Georgetown, MA (US)

Correspondence Address: WOLF GREENFIELD & SACKS, P.C., 600 ATLANTIC AVENUE, BOSTON, MA, 02210-2206, US

(73) Assignee: University of Massachusetts, Boston, MA (US)

(21) Appl. No.: 11/407,381

(22) Filed: Apr. 18, 2006

(51) Int. Cl. H01L 29/732

(52) U.S. Cl. 257/183

(57) ABSTRACT

A field effect transistor has a shifted gate such that the gate-source distance depends on the ratio of the threshold voltage to the drain voltage. In one embodiment, a switch may include two FETs: one FET in a series configuration and one FET in a shunt configuration. Providing a switch having at least one FET with a shifted gate allows increasing switching speed and decreasing insertion loss.

### BACKGROUND OF INVENTION

For microwave and radio frequency (RF) applications, such as radar electronics and wireless communications, a switch is often used to direct a signal to a transmission or a reception (T/R) path. One example is the routing of RF power to or from an antenna. In transmitting mode, the output amplifier is connected to the antenna to send a signal. In receiving mode, the signal received at the antenna is switched to the input circuitry. Size, isolation, insertion loss, power handling and switching speed can be important factors in T/R switches. Other important factors can include low distortion and clean transient switching. Currently, semiconductor transistors are typically used in T/R switches.

A T/R switch may include several transistors, e.g., field effect transistors (FETs), in a series and/or shunt configuration. A FET has three terminals: a source, a drain and a gate. During operation of the FET, current flows between source and drain terminals through a channel region. The gate electrode, positioned between the source and the drain, enables the current through the FET to be controlled based on the strength of the signal applied to the gate. The signal and bias applied to the gate, source and drain determines the electric field profile in the channel region between the source and the drain. The performance of the FET is determined by the profile of the electric field in the channel region.

### SUMMARY OF INVENTION

In a conventional FET with a single gate, the gate is positioned in the center of the FET, half way between the source and the drain. Embodiments of the invention relate to a switch, e.g., a T/R switch, having at least one FET with a shifted gate, either in a series configuration, shunt configuration or some combination of the two. The Applicants have appreciated that positioning the gate of at least one FET in a shifted position can enhance performance of a switch. The gate can be positioned based on a ratio of the threshold voltage of the FET to the drain voltage of the FET. For example, the gate-source distance (D_{gs}) can be determined approximately by multiplying the channel length, e.g., source to drain distance (D_{sd}), times the ratio of the threshold voltage (Vₜₕ) to drain voltage (_{V}d) of the FET. Therefore, D_{gs}=(Vₜₕ)×(D_{sd})/(V_{d}) is a design rule used to determine the approximate gate-source distance. The Applicants have discovered that providing a gate positioned closer to the source than the drain using this design rule can improve the switching speed and linearity of the switch by altering the electric field profile in the channel region of the FETs. In some embodiments of the invention, the switch has at least two FETs with gates shifted according to this design rule. One of the FETs may be in a series configuration and another FET may be in a shunt configuration.

One embodiment of the invention relates to a field effect transistor that includes a source, a drain and a gate. The gate is positioned a gate-source distance from the source the gate-source distance is approximately a threshold voltage of the field effect transistor times a drain-source distance divided by a voltage of the drain.

Another embodiment of the invention relates to a switch that includes a first field effect transistor and a second field effect transistor. The first field effect transistor has a first source, a first drain, and a first gate positioned a first gate-source distance from the first source. The first gate-source distance is determined based on a ratio of a threshold voltage of the first field effect transistor to a voltage of the first drain. The second field effect transistor has a second source, a second drain, and a second gate positioned a second gate-source distance from the second source. The second gate-source distance is determined based on a ratio of a threshold voltage of the second field effect transistor to a voltage of the second drain.

A further embodiment of the invention relates to a switch that includes a first field effect transistor and a second field effect transistor. The first field effect transistor has a first source, a first drain, and a first gate positioned a first gate-source distance from the first source. The first gate-source distance is approximately a threshold voltage of the field effect transistor times a first drain-source distance divided by a voltage of the first drain. The second field effect transistor has a second source, a second drain, and a second gate positioned a second gate-source distance from the second source. The second gate-source distance is approximately a threshold voltage of the second field effect transistor times a second drain-source distance divided by a voltage of the second drain.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a cross-section of a pHEMT with a shifted gate according to one aspect of the invention; and

FIG. 2 is a circuit diagram illustrating switch 200 according to one embodiment of the invention.

### DETAILED DESCRIPTION

As discussed above, prior T/R switches used FETs in series and shunt configurations. FETs in the series configuration had lower insertion losses than FETS in the shunt configuration. However, FETs in the shunt configuration provided better isolation than FETs in the series configuration. The Applicants have appreciated that it is desirable to provide a switch having low insertion loss, good isolation characteristics, and high switching speed. Such a switch may be particularly useful for microwave and radio frequency applications, such as radar electronics and wireless communications, e.g., cellular telephones. However, the embodiments of the invention are useful in a variety of other applications, and is not limited to T/R applications. Furthermore, embodiments of the invention are not limited to switch applications, but may be used in amplifier applications or any other suitable applications.

In one aspect of the invention, a switch includes one or more FETs with shifted gates. For example, the gate of each FET may be positioned closer to the source than to the drain. The Applicants have appreciated that a switch having FETs with gates positioned closer to the source than to the drain can improve the switching speed and insertion loss of the switch. Positioning the gate closer to the source alters the electric field in the channel region of the FET and affects parasitic capacitances such as the gate-source and gate-drain capacitances. The gate-source capacitance can be increased because of the relatively shorter distance between the source and the gate. The gate-drain capacitance can be decreased because of the relatively larger distance between the drain and the gate. This effect can be particularly useful in the shunt element for improving linearity.

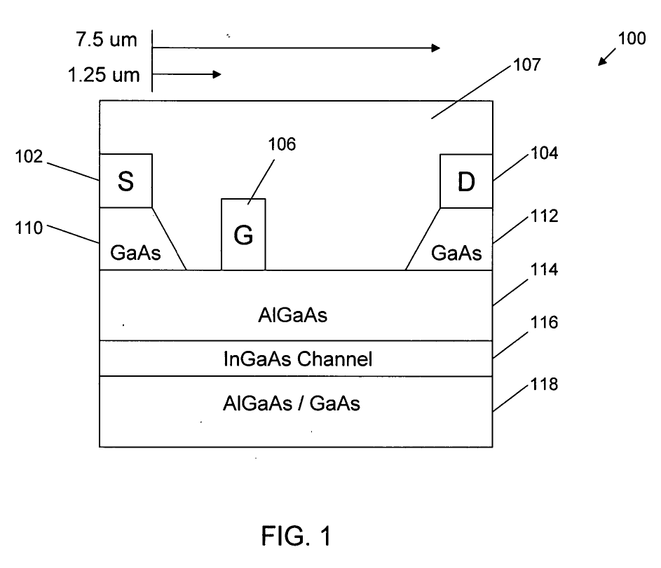

FIG. 1 is a cross section of a pseudomorphic high-electron-mobility transistor (pHEMT) 100 with a shifted gate, according to one embodiment of the invention. In this embodiment, pHEMT 100 includes a source 102, drain 104, and a gate 106. Source 102, drain 104 and gate 106 may be metallizations formed of any suitable material, e.g., a metal such as aluminum. Source 102, drain 104, and gate 106 may be separated by an insulating region 107 which may be any suitable insulating material such as silicon nitride or silicon dioxide. Gate 106 may form a Schottky contact with third semiconductor layer 114. In this embodiment, pHEMT 100 includes a first semiconductor region 110 and second semiconductor region 112, e.g., gallium arsenide (GaAs), a third semiconductor region 114, e.g., aluminum gallium arsenide (AlGaAs), a channel region 116, e.g., indium gallium arsenide (InGaAs), and a substrate 118, e.g., an AlGaAs/GaAs superlattice.

In accordance with the invention, gate 106 is shifted so that it is positioned closer to source 102 than to drain 104. Positioning gate 106 in a shifted position, e.g., closer to source 102, changes the electric field in the channel region 116. In particular, the Applicants have appreciated that the gate can be positioned based on a ratio of the threshold voltage of the FET to the drain voltage of the FET. For example, the gate-source distance (D_{gs}) can be determined approximately by multiplying the channel length, e.g., source to drain distance (D_{sd}), times the ratio of the threshold voltage (Vₜₕ) to drain voltage (V_{d}) of the FET. Therefore, D_{gs}=(Vₜₕ)×(D_{sd})/(V_{d}) may be used to determine the approximate gate-source distance. As one example, the threshold voltage may be 1.0 volts, the drain voltage may be 6.0 volts, and the distance between source 102 and drain 104 may be approximately 7.5 μm. Therefore the distance between source 102 and gate 106 may be approximately 1.5 μm, i.e., 1/6 of 7.5 μm. Positioning gate 106 using such a design rule can improve the performance of a switch, e.g., a T/R switch, by reducing the insertion loss and switching speed. In some circumstances, the position of the gate may be modified from the position described above to account for different transistor types, the level of doping in the channel or the use of intrinsic materials.

These dimensions are provided merely by way of example, and are not intended to be limiting. One of ordinary skill in the art would appreciate that the FET may be of any suitable size, and that the dimensions may be scaled accordingly. However, different dimensions and/or relative sizes between dimensions may be used, as the invention is not limited in this respect. Furthermore, the source and the drain terminals may be interchangeable in a symmetric FET, and the gate may be positioned according to the above design rule according to which terminals are chosen as the source and drain.

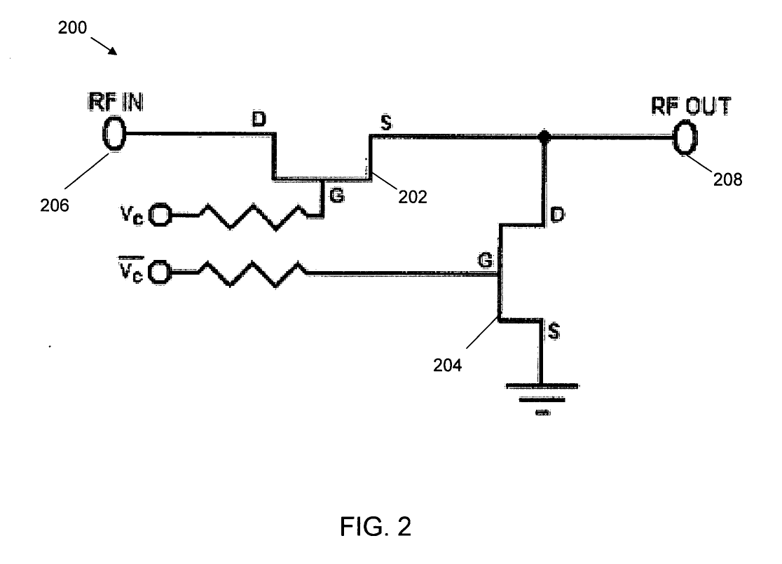

FIG. 2 is a circuit diagram illustrating switch 200 according to one embodiment of the invention. In this embodiment, switch 200 includes two FETs: first FET 202 in a series configuration and second FET 204 in a shunt configuration. The drain of FET 202 may be coupled to an input port 206 that receives an RF signal, and the source of FET 202 may be coupled to an output port 208 that provides an RF output for switch 200. The source of FET 204 may be coupled to ground for a reflective switch, or through a resistance or impedance to ground for a non-reflective switch. The drain of FET 204 may be coupled to output port 208.

Complementary control signals Vc and Vc′ are applied to the gates of FETs 202 and 204 for turning on and off switch 200. For example, when Vc is a high signal, the gate of FET 202 turns on FET 202, and the input signal provided at input port 206 is allowed to flow through FET 202 to output port 208. When Vc is high, Vc′ is low, causing the gate of FET 204 to turn off FET 204, substantially preventing a conductive path through FET 204 between output terminal 208 and ground. Thus, when Vc is high, switch 200 is turned on.

Conversely, when Vc is low, FET 202 turns off and substantially prevents the input port 206 from being coupled to output port 208. When Vc is low, Vc′ is high, thus turning on FET 204 and coupling output port 208 to ground. Thus, when Vc is low, switch 200 is turned off. However, these polarities are provided merely by way of illustration, and it should be appreciated that the polarities of the gate signals could be reversed, depending on the type of FET used. For example, NMOS FETs turn on in response to a high polarity signal, and PMOS FETs turn on in response to a low polarity signal.

In accordance with the invention, both FETs 202 and 204 may be FETs with shifted gates, such as pHEMT 100 described above and illustrated in FIG. 1. Thus, in one embodiment of the invention, switch 200 includes two pHEMTs: one in a series configuration and one in a shunt configuration. A switch that includes FETs, e.g., pHEMTs, with shifted gates can provide a faster switching speed and lower insertion losses than FETs with non-shifted gates, e.g., centered gates. The Applicants have fabricated the switch as illustrated in FIG. 2 with two pHEMTs as illustrated in FIG. 1. In operation, switch 200 allows an improvement in turn-on time of approximately 30%, and an improvement in turn-off time compared to a switch having FETs with non-shifted gates. Furthermore, switch 200 allows a reduction in insertion loss by a factor of approximately 1.6. These improvements in performance may be caused by the change in the electric field distribution in the FET channel caused by shifting the gate to be positioned closer to the source than to the drain. Furthermore, it is believed that the reduction in gate-drain capacitance reduces insertion losses caused by shunt FET 204, as well as improving linearity.

FIG. 2 illustrates one embodiment of the invention in which two FETs with shifted gates are used in a series/shunt switch configuration. However, it should be appreciated that a single FET, two FETs, or more than two FETs may be used, as the invention is not limited in this respect. Any suitable number of FETs may be used in the switch. The switch may have a single series FET, multiple series FETs, a single shunt FET, multiple shunt FETs, or any combination of above. The number of series and/or shunt elements used may depend upon the type of switch and the application in which it is used. Furthermore, not all of the FETs used in the switch need to have shifted gates.

As discussed above, aspects of the invention may be used in a switch application. However, embodiments of the invention are not limited to switch applications and may be used in other applications, e.g., amplifier applications. For example, a switch may be considered as an amplifier that operates at the extremes, e.g., either on or off. Embodiments of the invention may be used in amplifier applications, or in any other suitable applications such as mixers, shifters, etc.

As discussed above, FIG. 1 illustrates an example of a pHEMT 100 according to one aspect of the invention. However, it should be appreciated the present invention is not limited to pHEMTs, but may be applied to any suitable type of FET, e.g., MOSFETs or MESFETs. The invention is not limited as to the particular materials used for the various regions of the FET. The semiconductor regions may be any suitable semiconductor regions, such as silicon, germanium, gallium arsenide, gallium nitride, etc., as the invention is not limited in this respect. Furthermore, the gate, source and drain metallizations may be formed of any suitable conductive material, e.g., a metal such as aluminum. As discussed above, the insulating regions may be formed of any suitable insulating material, e.g., silicon nitride or silicon dioxide, or by a combination of materials.

Having thus described several aspects of at least one embodiment of the invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A field effect transistor comprising:
a source;
a drain; and
a gate positioned a gate-source distance from the source, the gate-source distance being approximately a threshold voltage of the field effect transistor times a drain-source distance divided by a voltage of the drain.

2. The switch of claim 1, wherein the field effect transistor is a pHEMT.

3. A switch, comprising:
a first field effect transistor having a first source, a first drain, and a first gate positioned a first gate-source distance from the first source, the first gate-source distance being determined based on a ratio of a threshold voltage of the first field effect transistor to a voltage of the first drain; and
a second field effect transistor having a second source, a second drain, and a second gate positioned a second gate-source distance from the second source, the second gate-source distance being determined based on a ratio of a threshold voltage of the second field effect transistor to a voltage of the second drain.

4. The switch of claim 3, wherein the first field effect transistor is coupled in a series configuration and the second field effect transistor is coupled in a shunt configuration.

5. The switch of claim 3, wherein the first field effect transistor is a pHEMT.

6. A switch, comprising:
a first field effect transistor having a first source, a first drain, and a first gate positioned a first gate-source distance from the first source, the first gate-source distance being approximately a threshold voltage of the field effect transistor times a first drain-source distance divided by a voltage of the first drain; and
a second field effect transistor having a second source, a second drain, and a second gate positioned a second gate-source distance from the second source, the second gate-source distance being approximately a threshold voltage of the second field effect transistor times a second drain-source distance divided by a voltage of the second drain.

7. The switch of claim 6, wherein the switch is a transmission and/or reception switch for coupling a radio frequency to and/or from an antenna.

8. The switch of claim 6, wherein the first field effect transistor is a pHEMT.

9. The switch of claim 6, wherein the first field effect transistor is coupled in a series configuration and the second field effect transistor is coupled in a shunt configuration.

10. The switch of claim 6, wherein the first gate is closer to the first source than to the first drain.
